(19) United States
(12) Patent Application Publication
(10) Pub. No.: US 2018/0268890 A1
(43) Pub. Date: Sep. 20, 2018

(54) REFRESH-FREE TFET MEMORY LATCH

(71) Applicant: COMMISSARIAT A L'ENERGIE ATOMIQUE ET AUX ENERGIES ALTERNATIVES, Paris (FR)

(72) Inventors: Navneet Gupta, Grenoble (FR); Amara Amara, Sceaux (FR); Costin Anghel, Vanves (FR); Adam Makosiej, Grenoble (FR)

(73) Assignee: COMMISSARIAT A L'ENERGIE ATOMIQUE ET AUX ENERGIES ALTERNATIVES, Paris (FR)

(21) Appl. No.: 15/916,585

(22) Filed: Mar. 9, 2018

(30) Foreign Application Priority Data
Mar. 10, 2017 (FR) 17 51955

(51) Int. Cl. G11C 11/409; G11C 11/419; G11C 11/4094; G11C 11/408; G11C 11/418

(52) U.S. Cl. CPC G11C 11/409; G11C 11/419; G11C 11/418; G11C 11/4085; G11C 11/4094

(57) ABSTRACT

Memory latch comprising:
a TFET;
a capacitor;
a storage node formed by the connection of a first terminal of the capacitor to a first electrode of the TFET;
a control circuit configured to supply a first electric potential on a second terminal of the capacitor, a second electric potential on the gate of the TFET and a third electric potential on a second electrode of the TFET, such that:
   when the stored potential is low, the TFET is reverse biased with a conduction current obtained by band-to-band tunneling with a value higher than a capacitor leakage current;
   when the stored potential is high, the TFET is reverse biased with an OFF state current value less than the capacitor leakage current.

### TECHNICAL FIELD AND PRIOR ART

This invention presents design and operation of TFET (“Tunnel Field-Effect Transistor”) refresh-free DRAM (“Dynamic Random Access Memory”) and SRAM (“Static Random Access Memory”) memory bit cells, or memory latches. The present invention is for example applicable for all the use cases where large data storage is required. For example, the memory latch of the invention may be used in a cache memory for embedded processors, multimedia processing, DSP (“Digital Signal Processor”)cores, or used as storage on-chip and/or off-chip. The memory latch of the invention is also relevant for the making of embedded systems which support different kind of application and have data storage and processing.

CMOS technology scaling is the key factor in addressing the demand of ever increasing complexity of VLSI (“Very Large Scale Integration”) designs adding more and more computation power on a die. In order to meet the overall performance requirements while scaling down the devices, high throughput memory technologies are becoming increasingly important. Conventionally, SoC's (“System-On-Chip”) relies on SRAMs in order to address the throughput/performance gap between CPU's and main memory (DRAM). However, SRAM's size and power consumption is of critical concern with the rapid growth in capacity requirements of high bandwidth memories. SRAMs are used as primary cache memory in almost all kind of processing systems.

Area overhead due to poor array density and leakage power consumption of high-throughput SRAMs is limiting factor in reduction of the silicon footprint and system cost.

In order to further reduce the die area and cost, DRAM has been explored as an alternative option. DRAMs are better in comparison to SRAMs in memory density and overall throughput. However, in order to scale DRAMs aggressively specific technology and process is used, e.g. vertical transistors and capacitors. This makes its inclusion of DRAMs in logic chips difficult and costly.

An intermediate solution which has been explored is use of embedded DRAMs (eDRAMs) which are denser than SRAMs and relatively easier to fabricate with CMOS technology for digital logic technology, as disclosed for example in the document Brain Ruth and al., “A 22 nm high performance embedded DRAM SoC technology featuring tri-gate transistors and MIMCAP COB”, VLSI Technology (VLSIT), 2013 Symposium on. IEEE, 2013. However, standard 1T1C DRAM structure is becoming ever more difficult to scale with technology, specifically because of difficulties in scaling the capacitance. In order to reduce the throughput penalty because of refresh requirements, capacitors with high capacity while having low leakage are required. This limits the scaling for DRAM capacitors, as per the ITRS (“International Technology Roadmap for Semiconductors”) roadmap 2009 to 2016, capacitor is increased by 20% in capacity while the transistor technology is scaled from 52 nm to 22 nm. Various techniques, like negative word line and high gate oxide thickness of capacitors, are used in DRAMs to reduce leakage and thus increase retention time. However, EOT (“Equivalent oxide thickness”) of 0.3 nm is suggested by ITRS for DRAM capacitors, resulting in significantly increased capacitor leakage.

In eDRAMs, capacitor size is reduced at the cost of retention time in order to optimize cost of process and silicon footprint. Another critical issue, especially for eDRAMs, is that the leakage increases significantly at high temperatures which is often the case for eDRAMs because of close proximity to compute intensive blocks like CPUs (“Central Processing Unit”)/GPUs (“Graphics Processing Unit”).

In order to further scale the dimensions, other than CMOS technologies have been explored. TFET was proposed as a possible solution to reduce leakage while having scalability as MOSFETs. The TFET operates by band-to band tunneling and therefore the subthreshold slope (S) is not limited to 60 mV/dec as in the case of CMOS. Fabricated TFETs with S as low as 30 mV/dec have already been measured. Progress on TFET devices has encouraged research on TFET circuits. Unidirectional behavior and negative differential resistance (NDR) properties are very promising to design circuits while addressing the issues of conventional CMOS circuits and architectures. In the documents Gupta Navneet and al., “Ultra-compact SRAM design using TFETs for low power low voltage applications”, 2016 IEEE International Symposium on Circuits and Systems (ISCAS. IEEE, 2016, and Costin Anghel and al., “30 nm Tunnel FET with improved performance and reduce ambipolar current”, IEEE Transactions on Electron Devices, Vol. 58, Issue 6, June 2011, ultra-low leakage and compact TFET SRAM cells are proposed using NDR property of TFETs. Because of unidirectional behavior of TFETs, conventional 1T1C DRAM architecture cannot work in a similar way as for CMOS.

### SUMMARY OF THE INVENTION

There is a need to propose a new memory bit cell, or memory latch, architecture which can address at least some of the drawbacks of the previously described memory latches, especially which is not negatively impacted by a significant increase of capacitor leakage and which can be used as a 1T1C DRAM latch.

Thus a memory latch is described comprising at least:
a first TFET;
a capacitor;
a storage node formed by the connection of a first terminal of the capacitor to a first electrode of the first TFET corresponding to the source or the drain of the first TFET;
a control circuit able to supply a first electric potential on a second terminal of the capacitor, a second electric potential on the gate of the first TFET and a third electric potential on a second electrode of the first TFET corresponding to the drain of the first TFET when the first electrode of the first TFET corresponds to the source of the first TFET, or to the source of the first TFET when the first electrode of the first TFET corresponds to the drain of the first TFET;

wherein the control circuit is configured to provide, during a retention of a bit stored in the storage node, the first, second and third electric potentials with values such that:
when the stored bit has a first value (low, i.e. bit ‘0’, or high, i.e. bit ‘1’), the first TFET is reverse biased in a state wherein a conduction current is obtained by band-to-band tunneling in the first TFET with a value higher than a leakage current of the capacitor;
when the stored bit has a second value different than the first value (high when the first value is low, or low when the first value is high), the first TFET is reverse biased with an OFF state current obtained in the first TFET with a value less than the leakage current of the capacitor.

According to another definition, a memory latch is proposed comprising at least:
a first tunnel field effect transistor, TFET;
a capacitor;
a storage node formed by the connection of a first terminal of the capacitor to a first electrode of the first TFET corresponding to the source or to the drain of the first TFET and configured to store a bit such that the low and high values of the electrical potential of the storage node are representative of the value of the stored bit;
a control circuit configured to supply a first electrical potential on a virtual ground line, a second electric potential on a word line connected to the gate of the first TFET and a third electric potential on a bit line;

wherein:
in a first configuration, a second terminal of the capacitor is connected to the virtual ground line, the first electrode of the first TFET corresponds to its source when the first TFET is n-type or to its drain when the first TFET is p-type, a second electrode of the first TFET, corresponding to its drain when the first electrode corresponds to the source or to its source when the first electrode corresponds to the drain, is connected to the bit line, or
in a second configuration, a second terminal of the capacitor is connected to the bit line, the first electrode of the first TFET corresponds to its drain when the first TFET is n-type or to its source when the first TFET is p-type, a second electrode of the first TFET, corresponding to its source when the first electrode corresponds to the drain or to its drain when the first electrode corresponds to the source, is connected to the bit line;

and wherein the control circuit is configured to provide, during the retention of a bit stored in the storage node, the first, second and third electric potentials with values such that:
when the stored bit has a first value, a first bias voltage applied between the source and the drain of the first TFET has an absolute value less than that of a second bias voltage applied between the first and second terminals of the capacitor and the first TFET is reverse biased such that a conduction current obtained by band-to-band tunneling in the first TFET has a higher value than a leakage current of the capacitor;
when the stored bit has a second value which is different from the first value, the first bias voltage has an absolute value greater than that of the second bias voltage and the first TFET is reverse biased such that an OFF state current obtained in the first TFET has a smaller value than the leakage current of the capacitor.

This memory latch forms a 1T1C DRAM memory latch which behaves as a static latch, without requirement of refresh. Refresh removal allows to:
increase the throughput of the system embedding memory latches of the invention (between around 10% and 15%);
save time;
simplify the control of the memory latches;
save power.

Another advantage of this memory latch is that the leakage current of the capacitor is used to maintain the retention of a bit in the storage node. Thus leakage current of the capacitor is here useful and not a drawback in this memory latch. Therefore, a capacitor with thin effective-oxide-thickness (EOT) with leakage higher than the one imposed by ITRS can be used, relaxing the pressure on the technology and enabling the scaling beyond ITRS prediction.

This memory latch may be implemented (but is not limited to) by using Si-TFET and MIM capacitor using 28 nm FDSOI-CMOS process which allows co-fabrication of CMOS and TFETs.

In addition, due to no refresh, the amount of capacitance required per node is reduces. This with thin EOT reduces the size and cost of capacitor fabrication significantly.

This memory latch can be designed in various ways, such that:

1) the source of the first TFET is connected to the capacitor, and the drain of the first TFET is connected to the bit line when the first TFET is n-type or to the virtual ground line when the first TFET is p type, or

2) the drain of the first TFET is connected to the capacitor, and the source of the first TFET is connected to the virtual ground line when the first TFET is n-type or to the bit line when the first TFET is p-type.

In a first configuration, the first electrode of the first TFET corresponds to the source of the first TFET when the first TFET is a n-type TFET or to the drain of the first TFET when the first TFET is a p-type TFET. In this case:
when the value of the stored bit is low, the first TFET is reverse biased in a state wherein a conduction current is obtained by band-to-band tunneling in the first TFET with a value higher than a leakage current of the capacitor when the first TFET is a n-type TFET, and the first TFET is reverse biased with an OFF state current obtained in the first TFET with a value less than the leakage current of the capacitor when the first TFET is a p-type TFET;
when the value of the stored bit is high, the first TFET is reverse biased with an OFF state current obtained in the first TFET with a value less than the leakage current of the capacitor when the first TFET is a n-type TFET, and the first TFET is reverse biased in a state wherein a conduction current is obtained by band-to-band tunneling in the first TFET with a value higher than a leakage current of the capacitor when the first TFET is a p-type TFET.

In a second configuration, the first electrode of the first TFET corresponds to the drain of the first TFET when the first TFET is a n-type TFET or to the source of the first TFET when the first TFET is a p-type TFET. In this case:
when the value of the stored bit is high, the first TFET is reverse biased in a state wherein a conduction current is obtained by band-to-band tunneling in the first TFET with a value higher than a leakage current of the capacitor;
when the value of the stored bit is low, the first TFET is reverse biased with an OFF state current obtained in the first TFET with a value less than the leakage current of the capacitor.

In other words, the control circuit may be configured to provide the first, second and third electric potentials with values such that:
in the first configuration, when the value of the electric potential of the storage node is low, the first TFET is reverse biased by the first bias voltage such that the conduction current obtained by band-to-band tunneling in the first TFET has a higher value than the capacitor leakage current
in the first configuration, when the value of the electric potential of the storage node is high, the first TFET is reverse biased by the first bias voltage such that the OFF state current obtained in the first TFET has a value lower than the leakage current of the capacitor;
in the second configuration, when the value of the electric potential of the storage node is low, the first TFET is reverse-biased by the first bias voltage such that the OFF state current obtained in the first TFET has a value lower than the leakage current of the capacitor;
in the second configuration, when the value of the electric potential of the storage node is high, the first TFET is reverse biased by the first bias voltage such that the conduction current obtained by band-to-band tunneling in the first TFET has a value which is higher than the leakage current of the capacitor.

The control circuit may be configured to provide, during the retention of a bit stored in the storage node, the first, second and third electric potentials such that the absolute value of the first electric potential is higher than the absolute value of the third electric potential, and that the absolute value of the second electric potential is higher than the absolute value of the first electric potential. For example, the control circuit may provide three or four different electric potentials to carry out the retention of a bit in the memory latch.

The control circuit may be configured to provide, during the retention of a bit stored in the storage node, the first, second and third electric potentials such that the absolute value of the first electric potential is equal to the value of an electric potential corresponding to a bit with a high value (bit ‘1’), and/or that the absolute value of the third electric potential is equal to the value of an electric potential corresponding to a bit with a low value (bit ‘0’).

The control circuit may be configured to provide, during the retention of a bit stored in the storage node, the first, second and third electric potentials such that the absolute value of the first electric potential is substantially equal to the high value of the electric potential of the storage node, and/or that the absolute value of the third electric potential is substantially equal to the low value of the electric potential of the storage node.

The control circuit may be configured to provide, during a writing of a bit in the storage node, the first, second and third electric potentials such that:
the first electric potential includes a write pulse triggering the writing of the bit in the storage node, and the value of the third electric potential may be representative of the value of the bit to be written, for example during at least a part of the write pulse;
when the value of the bit to be written is low or corresponds to the low value of the electric potential of the storage node, the first TFET may be reverse biased in a state wherein a conduction current is obtained by thermionic emission over the barrier formed in the first TFET during the write pulse, discharging the storage node through the first TFET;
when the value of the bit to be written is high or corresponds to the high value of the electric potential of the storage node, the first TFET may be forward biased.

The memory latch may be such that:
during the writing of a bit with a low value or value which corresponds to the low value of the electric potential of the storage node, the absolute value of the second electric potential is equal to or higher than the absolute value of the third electric potential the absolute value of the first electric potential during the write pulse is equal to or higher than the absolute value of the second electric potential, and the absolute value of the first electric potential before and after the write pulse is possibly between the absolute values of the second and third electric potentials, and
during the writing of a bit with a high value or value which corresponds to the high value of the electric potential of the storage node, the absolute value of the third electric potential is equal or higher than the absolute value of the second electric potential, and the absolute value of the first electric potential during the write pulse is equal or higher than the absolute value of the second electric potential, and the absolute value of the first electric potential before and after the write pulse is possibly less than the absolute values of the second and third electric potentials.

The control circuit may be configured to provide, during the writing of a bit in the storage node, the first and third electric potentials such that:
during the writing of a bit with a low value, the absolute value of the third electric potential is equal to the value of the electric potential corresponding to the bit with a low value, and/or
the absolute value of the first electric potential before and after the write pulse is equal to the value of the electric potential corresponding to a bit with a high value.

The memory latch may further comprise a bit line connected to a second electrode of the first TFET, and wherein the control circuit is configured to apply, during a reading of a bit stored in the storage node, a pre-charge electric potential on the bit line and then a pulse voltage on the gate of the first TFET such that the value of the electric potential on the bit line turns down during the pulse only if the value of the stored bit is low.

The memory latch may further comprise a second TFET having its gate connected to the storage node. The second TFET may comprise a first electrode which corresponds to the source when the second TFET is n-type or to its drain when the second TFET is p-type, linked to the word line.

The memory latch may further comprise:
a word line connected to the gate of the first TFET and to a first electrode of the second TFET, the first electrode of the second TFET being the source of the second TFET when the second TFET is a n-type TFET or the drain of the second TFET when the second TFET is a p-type TFET,
a write bit line connected to a second electrode of the first TFET,
a read bit line connected to a second electrode of the second TFET, which corresponds to its drain when the first electrode corresponds to its source or to its source when the first electrode corresponds to its drain.

and the control circuit may be configured to apply, during a reading of a bit stored in the storage node, a read pulse on the word line such that the value of an electric potential on the read bit line turns down during the pulse only if the value of the stored bit or of the electric potential of the storage node is high.

A DRAM latches array is also described, comprising:
several memory latches as previously disclosed and arranged according to an array of several rows and several columns;
several word lines, each one being connected to the gate of the first TFET of each of the memory latches belonging to a same row of the array;
several virtual ground lines, each one being connected to the second terminal of the capacitor of each of the memory latches belonging to a same row of the array;

and wherein:
each bit line is connected to each of the memory latches belonging to a same column of the array;
the control circuit is common to all the memory latches of the DRAM latches array and configured to supply the electric potentials to said memory latches through the bit lines, the word lines and the virtual ground lines.

The control circuit may be configured to perform a writing operation collectively for one row of memory latches of the array such that:
the absolute value of an electric potential applied on the word line connected to the memory latches of said one row of memory latches is higher than the absolute value of an electric potential applied on the word lines connected to the other memory latches, then
the absolute values of the electric potentials applied on all the bit lines are set according to the values of the bits to be written in said one row of memory latches, and then
a write pulse is applied on the virtual ground line connected to the memory latches of said one row of memory latches.

The control circuit may be configured to perform a read operation collectively for one row of memory latches of the array such that:
the absolute value of the electric potentials applied on all the word lines are low, then
pre-charge electric potentials are applied on all the bit lines, and then
a read pulse is applied on the word line connected to the memory latches of said one row of memory latches.

A SRAM latches array is also described, comprising:
several memory latches as previously described and arranged according to an array of several rows and several columns;
several word lines, each one being connected to the gate of the first TFET and the first electrode of the second TFET of each of the memory latches belonging to a same row of the array;
several virtual ground lines, each one being connected to the second terminal of the capacitor of each of the memory latches belonging to a same row of the array;

and wherein:
each read bit line and write bit line is connected to each of the memory latches belonging to a same column of the array;
the control circuit is common to all the memory latches of the SRAM latches array and configured to supply the electric potentials to said memory latches through the read bit lines, the write bit lines, the word lines and the virtual ground lines.

The control circuit may be configured to perform a writing operation collectively for one row of memory latches of the array such that:
the absolute value of an electric potential applied on the word line connected to the memory latches of said one row of memory latches is higher than the absolute value of an electric potential applied on the word lines connected to the other memory latches, then
the absolute values of the electric potentials applied on all the write bit lines are set according to the values of the bits to be written in said one row of memory latches, and then
a write pulse is applied on the virtual ground line connected to the memory latches of said one row of memory latches.

The control circuit may be configured to perform a read operation collectively for one row of memory latches of the array such that:
the absolute value of the electric potentials applied on all the word lines are high, then
a read pulse is applied on the word line connected to the memory latches of said one row of memory latches.

A flip-flop is also described comprising at least:
first and second memory latches as above described;
a first inverter having an input forming the input of the flip-flop and an output connected to the storage node of the first latch;
a second inverter having an input connected to the storage node of the first latch and an output connected to the storage node of the second latch.

### BRIEF DESCRIPTION OF THE DRAWINGS

This invention will be understood easier in view of the examples of embodiments provided purely for indicative and non-limiting purposes, in reference to the appended drawings wherein:

FIG. 1 shows the characteristic I_{D}(V_{DS}) of a reverse biased n-TFET, for different values of V_{GS};

FIGS. 2a-2c show symbolically the different behaviors of a reverse biased TFET;

FIG. 3 shows a 1T1C memory latch according to a particular embodiment;

FIG. 4 shows a 1T1C DRAM latches array according to a particular embodiment;

FIG. 5 shows waveforms obtained during a write operation in a 1T1C memory latch according to a particular embodiment;

FIG. 6 shows waveforms obtained during a read operation in a 1T1C memory latch according to a particular embodiment;

FIG. 7 shows a 2T1C memory latch according to a particular embodiment;

FIG. 8 shows a 2T1C SRAM latches array according to a particular embodiment;

FIG. 9 shows waveforms obtained during a write operation in a 2T1C memory latch according to a particular embodiment;

FIG. 10 shows waveforms obtained during a read operation in a 2T1C memory latch according to a particular embodiment;

FIG. 11 shows schematically an array of latches according to a particular embodiment;

FIG. 12 shows schematically a flip-flop including memory latches according to a particular embodiment;

FIG. 13 shows a 1T1C memory latch according to another particular embodiment;

FIG. 14 shows a 1T1C DRAM latches array according to another particular embodiment;

FIGS. 15 and 16 show waveforms obtained during a write operation in a 1T1C memory latch according to a particular embodiment.

Identical, similar or equivalent parts of the different figures described below have the same numeric references for the sake of clarity between figures.

The different parts shown in the figures are not necessarily drawn to scale, so as to make the figures more comprehensible.

The different possibilities (alternatives and embodiments) must not be understood to mutually exclude each other and can, thus, be combined with each other.

### DETAILED DESCRIPTION OF PARTICULAR EMBODIMENTS

TFETs are reverse-biased p-i-n gated junctions that operate by tunneling effect, in which the electrostatic potential of the intrinsic region is controlled by a gate terminal. The TFETs used in the SRAM memory latches described below are calibrated and designed on data similar to that disclosed in the document C. ANGHEL et al., “30-nm Tunnel FET with improved performance and reduce ambipolar current”, IEEE Transactions on Electron Devices, 2011.

For example:
the TFETs are built using Low-k (SiO₂) spacers and a High-k (HfO₂) gate dielectric;
the gate and the spacers lengths are 30 nm each;
the gate dielectric physical thickness is 3 nm;
the silicon film thickness (tSi) used to form the source, drain and channel regions is 4 nm.

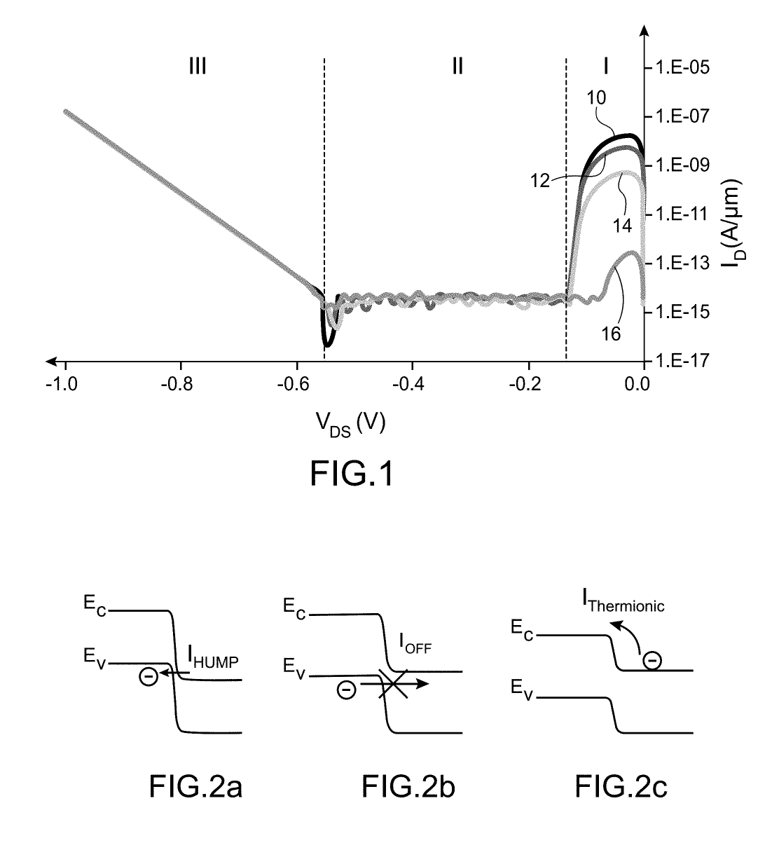

FIG. 1 shows the characteristic I_{D}(V_{DS}) of a reverse biased n-TFET, for different values of V_{GS}: V_{GS}=1 V for the curve 10, V_{GS}=0.75 V for the curve 12, V_{GS}=0.5 V for the curve 14 and V_{GS}=0.25 V for the curve 16. For this characteristic, three regions corresponding to three different behaviors of the TFET obtained for different ranges of values of V_{DS} can be distinguished as follows:
region I, which is named the “hump”, wherein a conduction current I_{HUMP} is obtained in the TFET by band-to-band tunneling (the charge injection mechanism corresponding to the band-to-band tunneling is symbolically shown in FIG. 2a);
region II, which is named the “flat-current region”, wherein the conduction current obtained in the region I is no longer obtained due to the non-overlapping bands (as shown symbolically in FIG. 2b). Only an OFF state current I_{OFF} is obtained in this region;
region III, which is named the “p-i-n turn-on”, wherein the charge injection mechanism is dominated by the thermionic emission over the barrier, creating a current named I_{Thermionic} as shown symbolically in FIG. 2c. In this region III, the TFET has a behavior similar to a short-circuit.

For the region III, the reverse biased output characteristic is named “unidirectional” due to the fact that the gate loses the control over the TFET for high negative drain voltages.

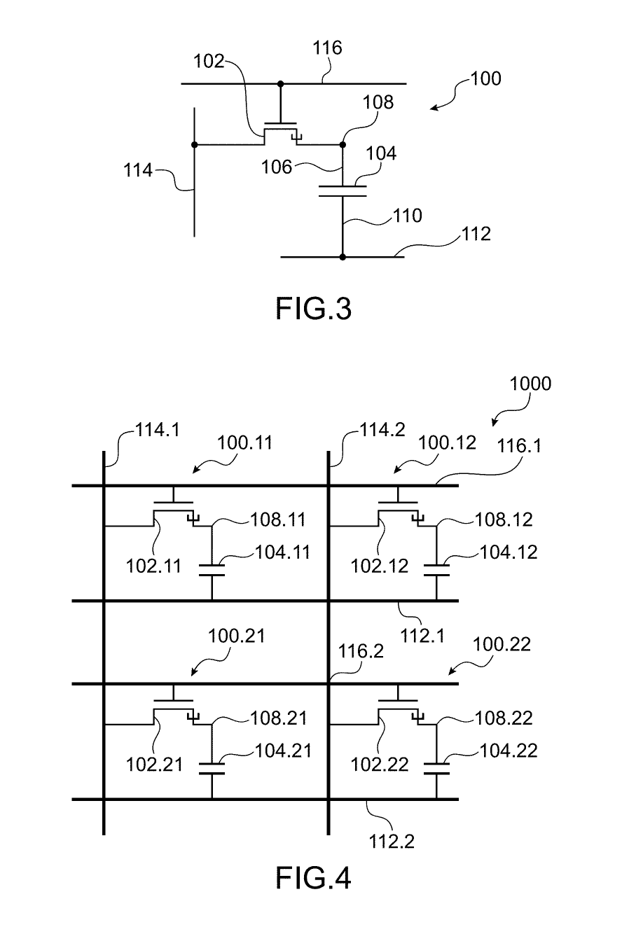

A TFET 1T1C memory latch 100 according to a particular embodiment is shown in FIG. 3 and described below. The latch 100 is here made according to a first configuration.

The latch 100 comprises a TFET 102, here an n-TFET, and a capacitor 104. The TFET 102 forms an access transistor of the latch 100, and is for example a Si-TFET. For example, the capacitor 104 can be a trench capacitor or a MIM (Metal-Insulator-Metal) capacitor. The source of the TFET 102 is connected to a first terminal 106 of the capacitor 104, this connection forming a storage node 108 of the latch 100. A second terminal 110 of the capacitor 104 is connected to a virtual ground line 112 of the latch 100.

The latch 100, which is intended to be used in an array of memory latches, also comprises a bit line 114 connected to the drain of the TFET 102 and a word line 116 connected to the gate of the TFET 102.

The bit line 114, the virtual ground line 112 and the word line 116 can be made in one metal level arranged above the active zone of the TFET of the latch 100.

The latch 100 also comprises a control circuit 101 (not shown in FIG. 3) configured to provide supply voltages, or electric potentials, on the virtual ground line 112, the bit line 114 and the word line 116.

An example of a DRAM latches array 1000 is shown in FIG. 4. The latches array 1000 comprises n rows and m columns of n×m latches 100.11 to 100.nm. On FIG. 4, only four latches 100, referenced 100.11-100.22, are shown. Data words are here stored horizontally, each in a row of latches 100.

Each word line 116 is connected to the latches 100 arranged on the same row of the array 1000. The word line referenced 116.x is thus connected to the gates of the TFETs 102.x1-102.xm belonging to the x-th row of the array 1000. On FIG. 4, only two word lines 116.1 (connected to the gates of the TFETs 102.11 and 102.12) and 116.2 (connected to the gates of the TFETs 102.21 and 102.22) are shown. Similarly to the word lines 116, each virtual ground line 112 is connected to the latches 100 arranged on the same row of the array. On FIG. 4, only two virtual ground lines 112.1 (connected to the capacitors 104.11 and 104.12) and 112.2 (connected to the capacitors 104.21 and 104.22) are shown.

Each bit line 114 is routed vertically, that is connected to all latches 100 arranged in a same column of the array 1000. In FIG. 4, only two bit lines 114.1 (connected to the drain of the TFETs 102.11 and 102.21) and 114.2 (connected to the drain of the TFETs 102.12 and 102.22) are shown.

The different operating modes (retention, writing and reading) of the memory latch 100 are described below.

The elements of the memory latch 100 are designed such that during a retention mode, or storing mode, of the latch 100, that is when a value of a bit is memorized and kept in the memory latch 100, I_{OFF} (TFET 102 OFF state current)«I_{LEAKCap} (capacitor 104 leakage current)«I_{HUMP} (TFET 102 hump current, corresponding to the I_{D} current in the region I shown in FIG. 1). For example, the value of the ratio I_{HUMP}/I_{LEAKCap} may be of about 10³, and the value of the ratio I_{LEAKCap}/I_{OFF} may be of about 10³. More generally, these currents may be such that I_{OFF}<I_{LEAKCap}<I_{HUMP}. For example, I_{OFF} may be less than 10⁻¹⁵ A/100 nm, I_{LEAKCap} may be equal to 10⁻¹⁴ A/cell and can be tuned by the different capacitances technologies (i.e. trench, cylinder/pedestal MIM, etc.), and I_{HUMP} can be tuned by the gate.

During a retention mode of the latch 100, whatever the value of the bit stored in the storage node 108 (a logical bit ‘1’ or ‘0’), the latch 100 behaves like a static storage memory. To obtain this behavior, the value of the electric potential applied on the bit line 114 is low and corresponds to that of the electric potential obtained on the storage node 108 when a logical bit ‘0’ is stored, e.g. 0V. The value of the electric potential applied on the virtual ground line 112 corresponds to that of the electric potential obtained in the storage node 108 when a logical bit ‘1’ is stored, e.g. 0.5V. The value of the electric potential applied on the word line 116 is high, especially higher than that of a logical bit ‘1’, e.g. 1V.

In general, low and high values of the electric potential of the storage node 108 are representative of the value of the stored bit. It is possible for example that a bit with a logic value ‘1’ corresponds to the high value of the electric potential maintained in the storage node 108, for example equal to about 0.5V, and that a bit with a logic value ‘0’ corresponds to the low value of the electric potential maintained in the storage node 108, for example equal to about 0V. According to another convention it is possible that a bit of logic value ‘1’ corresponds to the low value of the electric potential maintained in the storage node 108, and that a bit of logic value ‘0’ corresponds to the high value of the electric potential maintained in the storage node 108. In the rest of the description, a bit with logic value ‘1’ corresponds to the high value of the electric potential maintained on the storage node 108 and equal to about 0.5V, and that a bit with logic value ‘0’ corresponds to the low value of the electric potential maintained on the storage node 108 and equal to about 0V.

When a logical bit ‘0’ is stored in the storage node 108, the TFET 102 is biased with a low V_{DS} (0V) and a high V_{GS} (1V). Because the value of the electric potential on the virtual ground line 112 (e.g. 0.5V) is higher than that of the electric potential on the storage node 108 (e.g. 0V), the leakage current I_{LEAKCap} of the capacitor 104 tends to try to charge the storage node 108. This leads the TFET 102 to be reverse biased (because V_{DS} tends to become negative) and to have a behavior corresponding the previously disclosed region I wherein the conduction current I_{HUMP} is obtained in the TFET by band-to-band tunneling. The storage node 108 thus starts discharging due to I_{HUMP} current through the TFET 102 as soon as the value of the electric potential on the storage node 108 becomes higher than the value of the electric potential applied on the bit line 114, here equal to 0V. Since I_{HUMP}»I_{LEAKCap} (V_{GS} applied on the TFET 102 is here equal to 1V, which enables to have a high current I_{HUMP}), the latch 100 maintains the electric potential of the storage node 108 at 0V, or more generally to the value of the electric potential applied on the bit line 114, storing a logical bit ‘0’ statically.

When a logical bit ‘1’ is stored on the storage node 108, the voltage across the capacitor 104 is equal to 0V and the TFET 102 is reverse biased with V_{DS}=−0.5V. The behavior of the TFET 102 corresponds to the previously disclosed region II. The storage node 108 tends to discharge due to the I_{OFF} current through the TFET 102 while I_{LEAKCap} tends to charge the storage node 108 as soon as the value of the electric potential on the storage node 108 goes below the value of the electric potential one the virtual ground line 112 (e.g. 0.5V). Since I_{OFF}«I_{LEAKCap}, the value of 0.5V, or more generally the value of the electric potential applied on the virtual ground line 112, is maintained on the storage node 108, storing a logical bit ‘1’ statically.

Due to the static nature of storage during the retention mode, no refresh is required for the latch 100, which provides significant improvement in terms of throughput and energy consumption.

A write operation in the memory latch 100 is now described.

When the memory latch 100 belongs to a latches array 1000 as shown in FIG. 4, that is wherein each bit line 114 is shared by all the latches of a same column and wherein each word line 116 and virtual ground line 112 is shared by all the latches of a same row, a write operation is performed in all the latches of the row to which the latch 100 belongs because of the sharing of the word line and the virtual ground line by these latches.

The first step of the write operation is to pull down the values on all the word lines 116 to 0V, except for the word line connected to the row of latches intended to be written for which the value is kept high as in the retention mode, e.g. 1V.

The value of the electric potential applied on the bit line 114 associated with the latch 100 is set according to the value of the logical bit intended to be written in the storage node 108. In the example described here, when a logical bit ‘0’ is intended to be written in the latch 100, the value of the electric potential applied on the bit line 114 is equal to 0V. When a logical bit ‘1’ is intended to be written in the latch 100, the value of the electric potential applied on the bit line 114 is equal to 1.5V, which leads to a pulling up of the value of the storage node 108 due to the forward current of the TFET 102. This leads to a quasi-equalization of the voltages in the node 108 regardless if the latch stores a bit ‘0’ or ‘1’. This can be considered as an “initialization” phase for the write ‘1’ operation before that the pulse is applied on the virtual ground line 112.

When the array 1000 is considered, the writing operation is performed for all the memory latches belonging to one row of the array. In this case, the electric potentials applied on all the bit lines 114.1-114.m of the array 1000 are set according to the values of the bits intended to be stored in the memory latches of this row.

A write pulse is then applied on the virtual ground line 112 connected to the memory latch 100. During this pulse, the electric potential on the virtual ground line 112 is for example pulled up from 0.5V to 1.5V. This pulse on the virtual ground line 112 results in a ΔV on the storage node 108 similar to ΔV of this pulse (ΔV=1.5−0.5=1V in this example) due to capacitive coupling between both nodes on the two electrodes of the capacitor 104. Because of this, the value of the voltage on the storage node 108 tends to swing by the ΔV with the rising edge of the pulse. If a logical bit ‘0’ is stored in the storage node 108 and if the value of the electric potential on the bit line 114 is 0V, the value in the storage node 108 becomes 1V. If a logical bit ‘1’ is stored in the storage node 108 and/or if the value of the electric potential on the bit line 114 is 1.5V, the value on the storage node 108 becomes 1.5V.

With an electric potential on the storage node 108 is equal to 1V or 1.5V and a value on the bit line 114 equal to 0V, the TFET 102 is reverse biased and has a V_{DS} between −1V and −1.5V, that is has a behavior corresponding to the region III previously disclosed in relation with FIGS. 1 and 2. The value of the electric potential on the storage node 108 is discharged by thermionic emission through the TFET 102, thus reducing the value of V_{DS} on the TFET 102 and thus also the value of the electric potential in the storage node 108. When the value of the electric potential on the bit line 114 is equal to 1.5V, the discharge of the storage node 108 through the TFET 102, which is reverse biased and has a behavior corresponding to the region II, is minimal due to the small I_{OFF} in comparison to a latch having its bit line at 0V. This results in a voltage difference on the storage node 108 between the storing of a logical bit ‘0’ and a logical bit ‘1’.

This is followed by the falling edge of the pulse applied on the virtual ground line 112 during which the electric potential on the virtual ground line 112 is pulled down from 1.5V to 0.5V. A ΔV of −1V is thus applied on the storage node 108, bringing the value of the storage node 108 to 0V or 0.5V according to the value of the logical bit stored in this node 108.

At the end of this writing operation, the values on all the bit lines 114 of the latches array can be pulled down to the low value (0V) and the values on all the word lines 116 of the latches array can be pulled up to the high value (e.g. 1V), such that all the latches return in the retention mode.

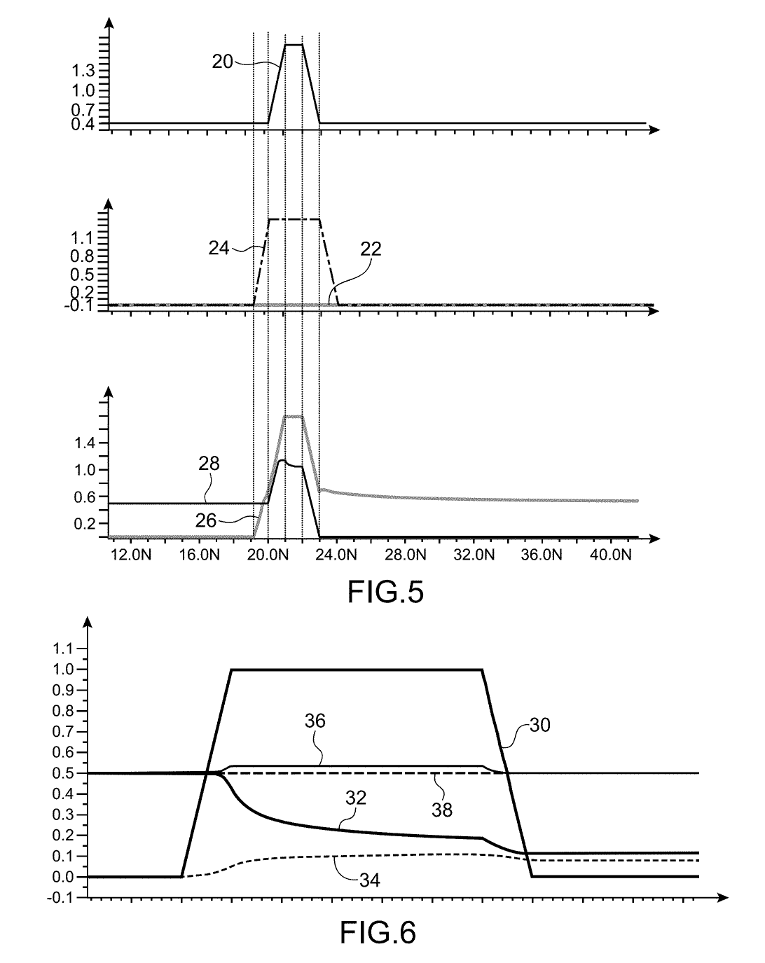

Waveforms of the signals used during a write operation is shown in FIG. 5.

The reference 20 designates the signal applied on the virtual ground line 112, including the write pulse. The reference 22 designates the signal applied on the bit line 114 during a ‘0’ writing, and the reference 24 designates the signal applied on the bit line 114 during a ‘1’ writing. The reference 26 designates the electric potential obtained in the storage node 108 during a ‘1’ writing, with ‘0’ initially stored in the storage node 108. The reference 28 designates the electric potential obtained in the storage node 108 during a ‘0’ writing, with ‘1’ initially stored in the storage node 108.

A read operation is performed by pulling down the values on all the word lines 116 for all the rows of latches 100. All the bit lines 114 are then pre-charged to 0.5V. The value on the word line 116 of the row of latches 100 intended to be read is then pulled up to 1V. During the read operation, the electric potentials applied on all the virtual ground lines 112 of the array are for example equal to 0.5V.

Read operation waveforms are shown in FIG. 6 for reading ‘0’ and ‘1’. The reference 30 designates the signal applied on the word line 116 of the row of latches 100 to read. The references 32 and 34 designate the electric potentials obtained on the bit line 114 and in the storage node 108 respectively, during a read operation of a latch in which a bit ‘0’ is stored. The references 36 and 38 designate the electric potentials obtained on the bit line 114 and in the storage node 108 respectively, during a read operation of a latch in which a bit ‘1’ is stored.

If a bit ‘1’ is stored in the read latch 100, the bit line 114 connected to this latch remains on the pre-charged value of 0.5V, while the value of the electric potential on the bit line 114 discharges if a bit ‘0’ is stored in this latch. As shown by the curve 34, the read operation changes the value of the electric potential in the storage node 108 wherein a ‘0’ is stored. Therefore, after a read operation, a write back operation can be carried out in order to re-write the previously stored values in the latches.

During the reading of a bit ‘0’ stored in the storage node 108, the bit line 114 discharge occurs due to the charge sharing between the capacitance formed by the bit line 114 and the capacitor 104 connected to the storage node 108. Unlike in a classical CMOS DRAM wherein the value of the capacitance connected to the storage node 108 depends on the leakage through the access transistor/capacitor and retention time requirement, the capacitor value requirement in the latch 100 is relaxed and a capacitance value, formed by the capacitor 104, equal to the bit line 114 capacitance is implemented in order to get e.g. a 0.25V discharge, or more generally a sufficient discharge, on the bit line 114 by charge sharing after the activation of the read operation by pulling up the word line 116. This allows to reduce the value of the capacitor 104.

During read and write operations, the unselected rows of latches of the array 1000 have floating storage nodes because the TFETs 102 in these latches are OFF with a word line voltage equal to 0V. Once the access (read or write) is finished, the 0V (logical ‘0’) is retained/restored by the TFET 102, while, value of logical ‘1’, e.g. 0.5V, is always restored by the leakage current I_{LEAKCap} of the capacitor 104 as previously explained for the retention mode.

The values of the electric potentials applied during retention, write and read operations in the latch 100 may differ from those given above.

A DRAM memory can be implemented with several arrays 1000 of memory latches 100. Such memory can comprises several sub-blocks implemented using the arrays of latches. The bit lines, word lines and virtual ground lines are local to each sub-block which can have multiplexed output. The output of the memory can be placed on global bit lines while reading which are common for full memory bank. The word line drivers and column decoder for selecting the multiplexed output can be placed on the sides shared between two sub-blocks on both sides of the driver. Since a full row is selected, it works as a distributed word line driving logic. For write operation, high capacitance on the virtual grounds has to be pulsed. This may be done by big shared driver which can be placed on top and bottom of the arrays, and could also be shared for blocks above and below the driver using transmission gate multiplexers for the selection. There is a single shared driver which can drive any row either above or below, depending on the selected access through the transmission gates. This is done to reduce the area and leakage power consumption of the periphery. Dual word line drivers can be implemented with two latch row pitch.

The proposed DRAM can be used for implementing DDR (Dual-Data Rate) memories for standalone chips or embedded DRAMs. In case of DDR implementation, because of the refresh removal, 3.8% and 7.8% throughput can be gained compared to a standard CMOS DRAM (i.e. assuming minimum penalty because of refresh) for less than 85° C. and above 85° C., respectively. In an actual running system, the loss because of refresh cycles, which are interrupting running traffic on DDR, may results in significantly more throughput loss.

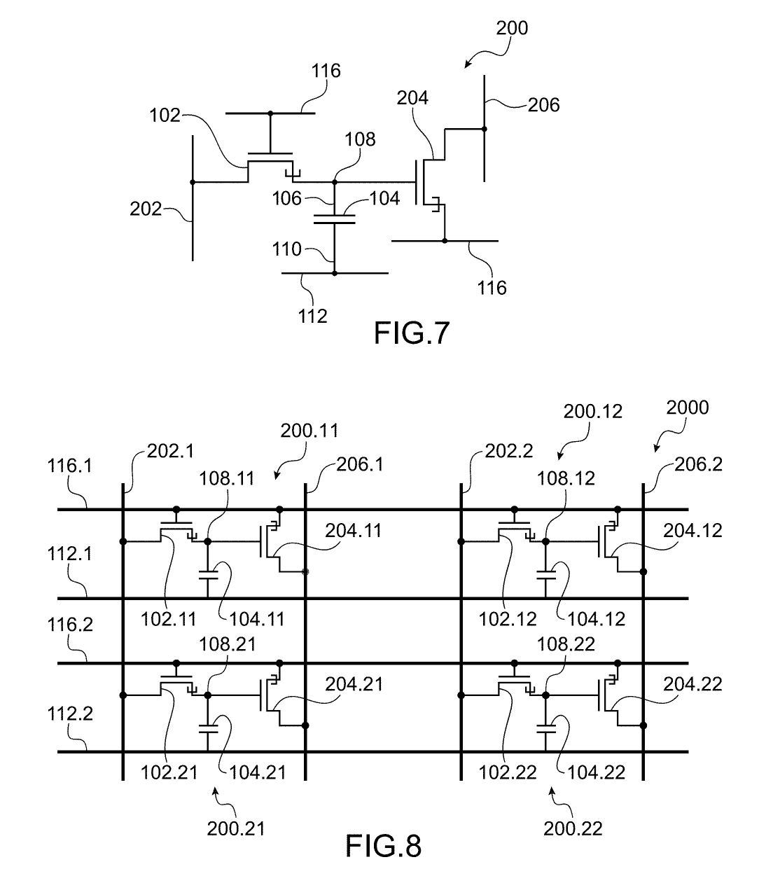

A TFET 2T1C memory latch 200 according to a particular embodiment is shown in FIG. 7 and described below.

Similarly to the previously disclosed memory latch 100, the memory latch 200 comprises the TFET 102, named here first TFET 102, the capacitor 104, the virtual ground line 112 and the word line 116. The drain of the first TFET 102 is connected to a write bit line 202. The latch 200 also comprises a second TFET 204. The gate of the second TFET 204 is connected to the storage node 108. The source of the second TFET 204 is connected to the word line 116 and the drain of the second TFET 204 is connected to a read bit line 206.

The latch 200 also comprises the control circuit 101 (not shown in FIG. 7) configured to apply electric potentials on the virtual ground line 112, the write bit line 202, the read bit line 206 and the word line 116.

An example of 2T1C SRAM latches array 2000 is shown in FIG. 8. The latches array 2000 comprises n rows and m columns of n×m latches 200.11 to 200.nm. On FIG. 8, only four latches 200, referenced 200.11-200.22, are shown. Data words are here stored horizontally, each in a row of latches 200.

Each word line 116 is connected to latches 200 arranged on the same row of the array 2000. The word line referenced 116.x is thus connected to the gates of the first TFETs 102.x1-102.xm and to the sources of the second TFETs 204.x1-204.xm belonging to the x-th line. On FIG. 8, only two word lines 116.1 (connected to the gates of the first TFETs 102.11 and 102.12 and to the sources of the second TFETs 204.11 and 204.12) and 116.2 (connected to the gates of the first TFETs 102.21 and 102.22 and to the sources of the second TFETs 204.21 and 204.22) are shown. Similarly to the word lines 116, each virtual ground line 112 is connected to the latches 200 arranged on the same row. On FIG. 8, only two virtual ground lines 112.1 (connected to the capacitors 104.11 and 104.12) and 112.2 (connected to the capacitors 104.21 and 104.22) are shown.

Each write bit line 202 and read bit line 206 is routed vertically, that is connected to all latches 200 arranged in a same column of the array 2000. In FIG. 8, only two write bit lines 202.1 (connected to the drain of the first TFETs 102.11 and 102.21) and 202.2 (connected to the drain of the first TFETs 102.12 and 102.22), and two read bit lines 206.1 (connected to the drain of the second TFETs 204.11 and 204.21) and 206.2 (connected to the drain of the second TFETs 204.12 and 204.22) are shown.

The different operating modes (retention, writing and reading) of the latch 200 are described below.

In this latch 200, a static latch is implemented using leakage NDR property of the first TFET 102 and capacitor 104 similarly to the previously disclosed memory latch 100. With the condition that I_{OFF} (TFET 102 OFF state current)«I_{LEAKCap} (leakage current through the capacitor 104)«I_{Hump} (TFET 102 hump current, corresponding to the I_{D} current in the region I shown in FIG. 1), the latch formed by the first TFET 102 and the capacitor 104 stores the value of a logical bit ‘0’ or ‘1’ statically, similarly to the static latch formed by the previously disclosed memory latch 100. During the retention mode, the electric potential applied on the virtual ground line 112 is for example equal to 0.5V, the one applied on the write bit line 202 is for example equal to 0V, the one applied one the read bit line 206 is for example equal to 1V, and the one applied on the word line 116 is for example equal to 1V.

In the memory latch 200, the second TFET 204 is used as a read port of the memory latch 200 and enables to isolate the read bit line 206 from the storage node 108 during the retention.

Write operation carried out in the memory latch 200 is similar to the previously described write operation carried out in the memory latch 100. In the array 2000, all the rows of latches 200 are having its word line 116 pulled down (e.g. equal to 0V) except the one written for which the value is kept high as in the retention mode, e.g. 1V. The electric potential applied on the write bit lines 202 is pulled up (e.g. equal to 1.5V) or down (e.g. equal to 0V) according to values to be written (logical bit ‘1’ or ‘0’, respectively). The value of the electric potentials applied on all the read bit lines are equal to 0V.

For each memory latch 200 belonging to the written row of latches and into which a logical bit ‘1’, high values of the electric potentials applied on the write bit line 202 and the word line 116 pulls up the latch 200 by a forward current (I_{ON}) in the first TFET 102. A write pulse with positive ΔV (e.g. a pulse between 0.5V and 1.5V) is applied on the virtual ground line 112 of the row of latches, this write pulse forming a word select signal. The electric potentials applied on the virtual ground lines of the other row of latches 200 have an unchanged value, e.g. equal to 0.5V. Due to highly capacitive coupling between the virtual ground line 112 and the storage node 108 in each latch 200 of the written row, the write pulse ΔV applied on the virtual ground line 112 try to induce ΔV in the storage node 108 (i.e. ΔV of ˜1V for this example).

Therefore, with rising edge of the write pulse, the storage node 108 will start swinging by 1V. This results in expected value of 1V for a storage nodes storing logical ‘0’ and for which the write bit line is at 0V. All the other storage nodes written start rising up to ˜1.5V, including the storage nodes having write bit lines high and/or storing ‘1’. With a storage node 108 rising more than 1V with write bit line 202 at 0V, first TFET 102 is reverse biased in region III (refer FIG. 1) and will discharge storage node 108 and decrease V_{DS} on the first TFET 102 by thermionic emission. This results in limiting the voltage on the storage node 108. Unlike latch having write bit line 202 at 0V, the discharge is minimal (due to I_{OFF}) for latches having word bit lines at 1.5V. This results in voltage difference on storage nodes 108 between written logical values of ‘0’ and ‘1’. After finishing the write, write bit line 202 is pulled down and falling edge of the write pulse on the virtual ground line 112 brings the storage node to 0V and 0.5V for latches which had write bit line at 0V and 1.5V, respectively.

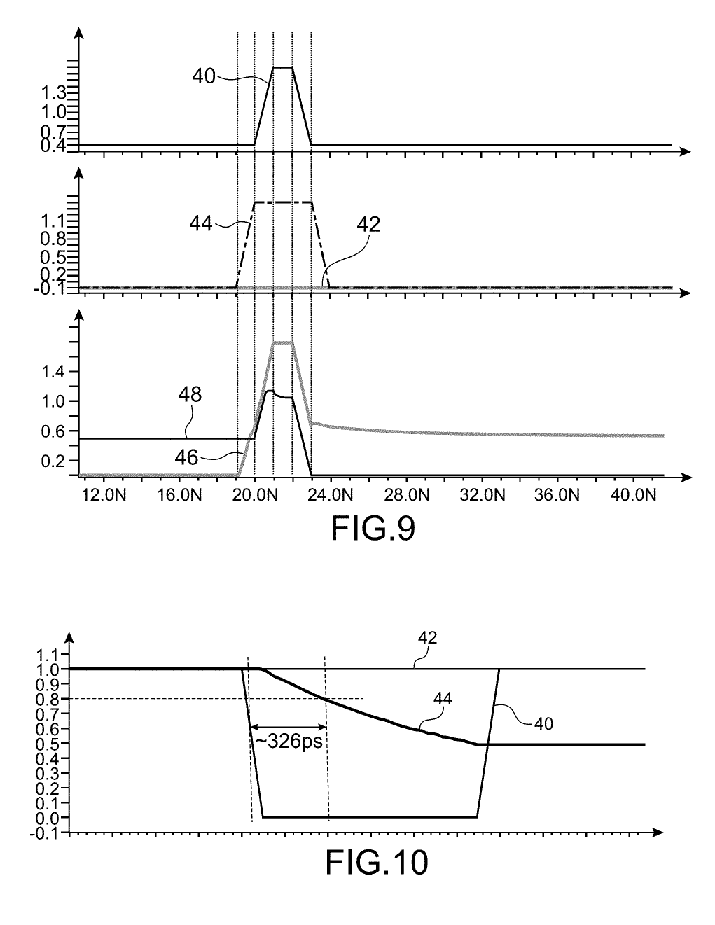

Write waveforms obtained for this write operation are shown on FIG. 9. The reference 40 designates the signal applied on the virtual ground line 112, including the write pulse. The reference 42 designates the signal applied on the write bit line 202 during a ‘0’ writing, and the reference 44 designates the signal applied on the write bit line 202 during a ‘1’ writing. The reference 46 designates the electric potential obtained in the storage node 108 during a ‘1’ writing, with ‘0’ initially stored in the storage node 108. The reference 48 designates the electric potential obtained in the storage node 108 during a ‘0’ writing, with ‘1’ initially stored in the storage node 108.

At the end of write operation, word line and write bit line are back to the corresponding retention electric potentials.

A read operation is performed using the read bit line 206 and the word line 116. The word line 116 connected to the row of memory latches 200 intended to be read is pulled down (e.g. 0V). All read bit lines 206 are pre-charged to 1V, and the electric potentials applied on all the write bit lines 202 are here equal to 0V.

With the word line 116 pulled down, the second TFET 204 in each read memory latch 200 is switched ON or OFF depending on the value in the latch is ‘1’ or ‘0’, respectively. During the reading of a bit ‘0’, the electric potential of the read bit line 206 connected to the read latch 200 remains on the pre-charged value of 1V. During the reading of a bit ‘1’, the electric potential of the read bit line 206 connected to the read latch 200 discharges. This difference between the values obtained on the read bit line 206 according to value of the stored bit enables to identify the value of the stored bit.

Waveforms obtained during the reading of a bit ‘0 and a bit ‘1’ in the memory latch 200 are shown in FIG. 10. The reference 40 designates the signal applied on the word line 116 of the row of latches 200 to read. The references 42 and 44 designate the voltages obtained on the read bit line 206 during a read operation of a latch in which a ‘0’ and a ‘1’ is stored, respectively.

The memory latches 200 can be floating during write operations, therefore, the capacity value of the capacitors 104 can be adapted according to the stability margin required during read and write operation. The value of the capacitors 104 is for example equal to the capacitance value of the read bit line 206. During write operations the unselected rows of latches are having floating storage nodes because of the OFF state of the first TFET 102 in these latches due to the stored value of 0V or 0.5V. Once the read operation is finished, the 0V (logical ‘0’) is restored by the first TFET 102, while value of logical bit ‘1’ is stable always, i.e. 0.5V, due to leakage current obtained through the capacitor 104.

Contrary to the memory latch 100, the read operation performed in the memory latch 200 does not destroy the logical bits ‘0’ stored. No write back operation is required.

The values of the electric potentials applied during retention, write and read operations in the latch 200 may differ from those given above.

Similarly to the previously disclosed DRAM memory formed by several arrays 1000 of memory latches 100, a SRAM memory can be implemented with several arrays 2000 of memory latches 200. Such memory can comprises several sub-blocks implemented using the arrays of latches. The read bit lines, write bit lines, word lines and virtual ground lines are local to each sub-block which can have multiplexed output.

The memory latches 200 can be designed with planar TFETs in 28 nm FDSOI CMOS process with MIM capacitors. The read bit line 206, the write bit line 202, the virtual ground line 112 and the word line 116 can be made in one metal level arranged above the active zone of the TFETs of the latch 200.

Unlike the high EOT of the capacitors which is used to reduce leakage, the proposed memory latches 100, 200 uses thinner EOT which results in reduced area and higher leakage in the capacitor 104.

FIG. 12 shows a flip-flop 3000 implemented with two memory latches 100.1, 100.2 similar to the latch 100 previously disclosed.

The flip-flop 3000 comprises a first synchronous inverter 3002 having its input forming the input of the flip-flop 3000. The output of the inverter 3002 is connected to the storage node 108.1 of the first memory latch 100.1. The storage node 108.1 is also connected to the input of a second synchronous inverter 3004. The output of the second synchronous inverter 3004 is connected to the storage node 108.2 of the second memory latch 100.2 which forms the output of the flip-flop 3000. In the configuration shown in FIG. 12, the storage node 108.2 is connected to the input of an optional third inverter 1006 the output of which forming in this case the output of the flip-flop 3000.

The behavior of the memory latches 100.1, 100.2 is similar to that previously disclosed for the memory latch 100 thanks to electric potentials VD, GND and VD applied on these latches 100.1, 100.2.

The synchronization of the signals inside the flip-flop 3000 is obtained thanks to the clock signal CLK applied on the clock input of the first synchronous inverter 3002 and the complementary clock signal CLKN (having an opposite value than that of the clock signal CLK) applied on the clock input of the second synchronous inverter 3004.

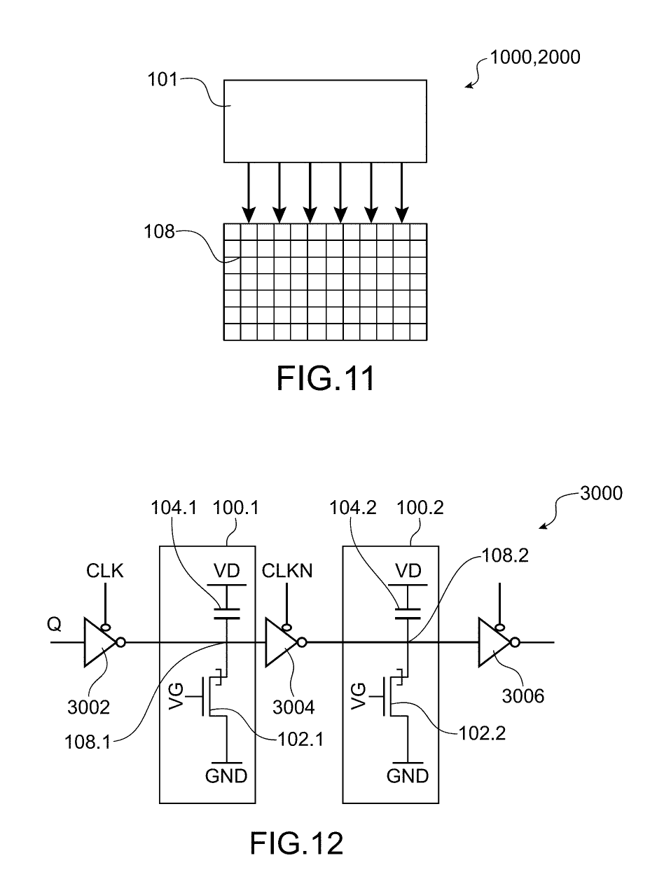

The FIG. 11 shows schematically an array 1000 or 2000, and also the control circuit 101 electrically coupled to the various elements (TFET 102, 204, capacitor 104) of the latches 100, 200 of this array which forms a matrix of storage nodes 108. The arrows shown on this figure represent the electrical connections between the control circuit 101 and the various lines of the arrays of latches through which the electric potentials are sent.

The control circuit 101 can also be electrically coupled to the elements of latches 100.1 and 100.2 of the flip-flop 3000 to apply the electric potentials on the elements of these latches and the signals CLK and CLKN on the inverters 3002, 3004.

In the above description, all the TFET used are n-type, or n-TFET. However, the latches 100, 200 can be implemented using p-type TFET, or p-TFET. In this case, the electrodes of the p-TFET connected to the other elements (lines, capacitor 104) of the latch are chosen such that the behavior of this latch is similar to the above described behavior. For example, for the latch 100 previously described, if the first TFET 102 is a p-TFET, the source of this p-TFET is connected to the bit line 114 and the drain of the p-TFET is connected to the storage node 108. When p-TFET are used, the value of the different electric potentials applied are also adapted in order to keep the previously disclosed behavior of the latch. The latch 200 can be implemented using n-TFET and/or p-TFET.

As a variant, according to a second configuration, it is also possible that the latches 100, 200 are implemented such that the electrode of the first TFET 102 connected to the storage 108 corresponds to the drain of the first TFET 102 when the first TFET 102 is a n-type TFET or to the source of the first TFET 102 when the first TFET 102 is a p-type TFET.

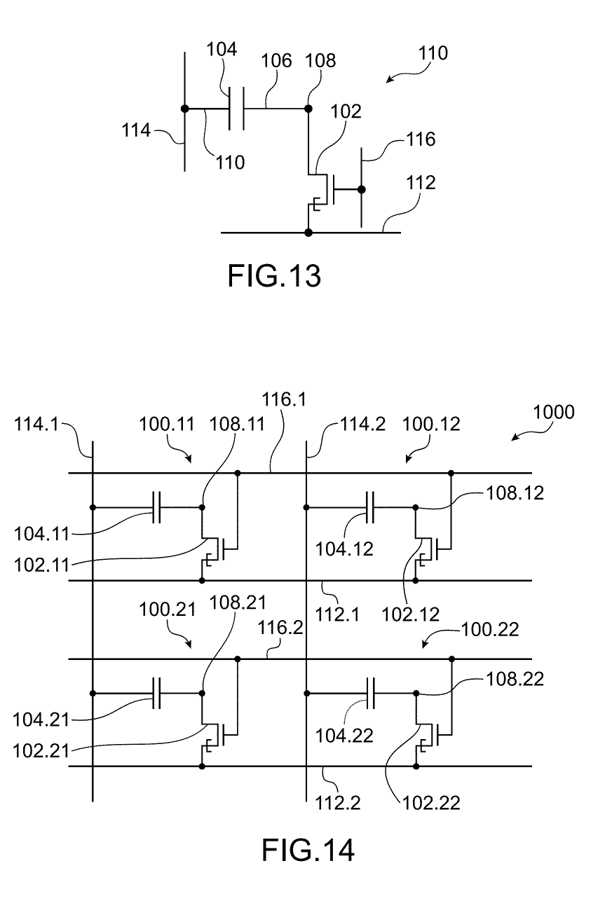

FIG. 13 shows a latch 100 according to this second configuration.

The latch 100 comprises the n-type TFET 102 and the capacitor 104. The drain of the TFET 102 is connected to the first terminal 106 of the capacitor 104, this connection forming the storage node 108 of the latch 100. The second terminal 110 of the capacitor 104 is connected to the bit line 114, the source of the TFET 102 is connected to the virtual ground line 112 and the gate of the TFET 102 is connected to the word line 116. The latch 100 also comprises the control circuit 100, which is not visible in FIG. 13.

An example of an array of DRAM latches 1000 is shown in FIG. 14. The latch array 1000 comprises n rows and m columns of n×m latches 100.11 to 100.nm. In FIG. 14 only four latches 100, with references 100.11 to 100.22, are shown. Data words are here stored horizontally, each in a row of latches 100.

Each line of words 116 is connected to the latches 100 arranged in the same row of the array 1000. The line of words with reference 116.x is thus connected to the gates of the TFETs 102.x1 to 102.xm belonging to the xth row of the array 1000. In FIG. 14, only two lines of words 116.1 (connected to the gates of the TFETs 102.11 and 102.12) and 116.2 (connected to the gates of the TFETs 102.21 and 102.22) are shown. In a similar manner to the word lines 116, each virtual ground line 112 is connected to the latches 100 arranged in the same line of the array. In FIG. 14, only two virtual ground lines 112.1 (connected to the sources of the TFETs 102.11 and 102.12) and 112.1 (connected to the sources of the TFETs 102.21 and 102.22) are shown.

Each bit line 114 is routed vertically, that is, connected to all latches arranged in a given column of the array 1000. In FIG. 14, only two bit lines 114.1 (connected to capacitors 104.11 and 104.21) and 114.2 (connected to capacitors 104.12 and 104.22) are shown.

As in the first configuration, the elements of the memory latch 100 are designed so that during a retention mode, or storage mode of the latch 100, namely when a value of a bit is stored and kept in the memory latch 100, I_{OFF} (OFF state current of TFET 102)«I_{LEAKcap} (leakage current of capacitor 104)«I_{HUMP} (hump current of TFET 102, which corresponds to the current I_{D} in the region I shown in FIG. 1). For example, the value of the ratio I_{HUMP}/I_{LEAKcap} may be about 10³, and the value of the ratio I_{LEAKcap}/I_{OFF} may be about 10³. More generally these currents may be such that I_{OFF}<I_{LEAKCap}<I_{HUMP}.

In this case, the values of the electric potentials applied on the first TFET 102 and the capacitor 104 of the latch 100, 200 are adapted to have a behavior of the latch similar to the one above described. For example, during a retention of a bit in the latch, the electric potentials applied on the latch 100, 200 are chosen such that:
when the value of the electric potential of the storage node 108 is high, the first TFET 102 is reverse biased in a state wherein a conduction current is obtained by band-to-band tunneling in the first TFET 102 with a value higher than a leakage current of the capacitor 104;
when the value of the electric potential of the storage node 108 is low, the first TFET 102 is reverse biased with an OFF state current obtained in the first TFET 102 with a value less than the leakage current of the capacitor 104.

For example, during a retention phase a potential equal to 0V may be applied on bit line 114, a potential equal to 0.5V may be applied on virtual ground line 112, and a potential equal to 1V may be applied on the word line 116.

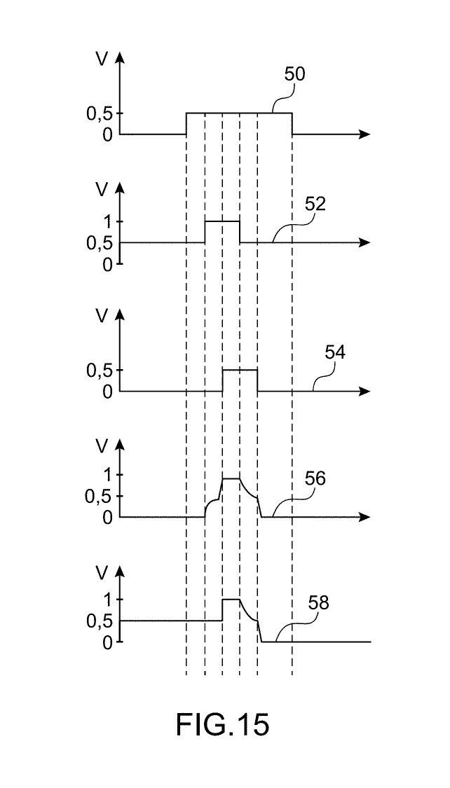

The curves shown in FIG. 15 correspond to examples of electric potentials applied during a write phase of an electric potential of low value, here 0V, in the storage node 108 of latch 100 previously described in connection with FIGS. 13 and 14. In this figure, the reference 50 designates the electric potential on the word line 116, reference 52 designates the electric potential on the virtual ground line 112, reference 54 designates the electric potential on the bit line 114, the reference 56 designates the electric potential on the storage node 108 when the value initially stored corresponds to the low value, and reference 58 designates the electric potential on the storage node 108 when the value initially stored corresponds to the high value, for example equal to 0.5V.

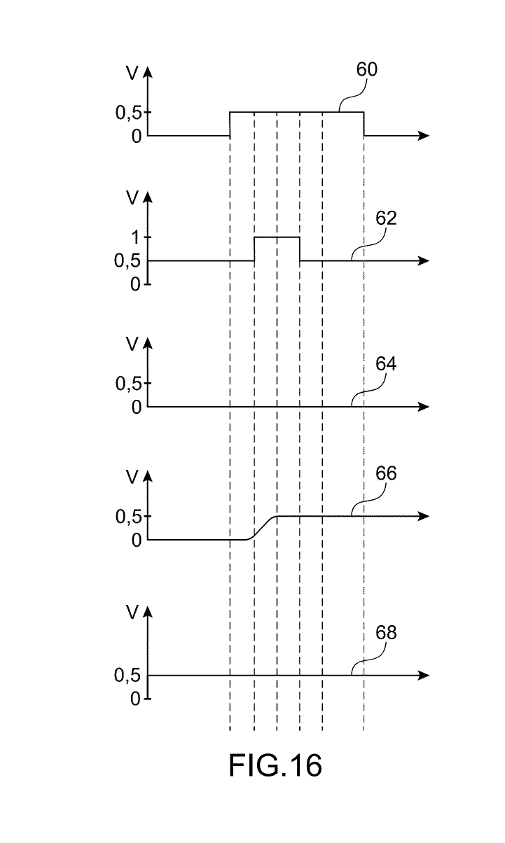

The curves shown in FIG. 16 correspond to examples of electric potential applied during a write phase of an electric potential of high value, here 0.5V, in the storage node 108 of the latch 100 previously described in connection with FIGS. 13 and 14. In this figure, reference 60 designates the electric potential on the word line 116, reference 62 designates the electric potential on the virtual ground line 112, reference 64 designates the electric potential on the bit line 114, reference 66 designates the electric potential on the storage node 108 when the initially stored value corresponds to the low value, and reference 68 designates the electrical potential on the storage node 108 when the initially stored value corresponds to the high value.

A read operation performed on the latch 100 according to the second configuration is similar to that performed on latch 100 according to the first configuration. It should be noted however that during a read operation performed on the latch 100 according to the second configuration it is the electrical potential obtained on virtual ground line 112 which is read and not that on the bit line 114 as is the case in the first configuration. Thus in a DRAM latches array 1000 such as shown in FIG. 14, line by line reading achieves reading of all the values of the latches present in the line that is read, which may, for example, allow a mean value of the values stored in the latches present on the line that is read to be obtained. In order to perform individual reading of the latches, the latches are in this case made by adding a second TFET 204, as in the latch 200 previously described in connection with FIGS. 7 and 8. In this case the second terminal 110 of the capacitor 104 is connected to a write bit line 202, the gate of the second TFET 204 is connected to the storage node 108, the source of the second TFET 204 is connected to the word line 116 and the drain of the second TFET 204 is connected to a read bit line 206.

Moreover, as for the first configuration, the TFET 102 (and/or TFET 204 for latch 200) may be p-type. In this case the electrodes of the p-TFET connected to the other elements (lines, capacitor 104) of the latch are chosen such that the behavior of this latch is similar to the behavior described above. For example, for the latch 100 previously described in connection with FIG. 13, if the first TEFT 102 is a p-TFET the source of this p-TFET is connected to the storage node 108 and the drain of the p-TFET is connected to the virtual ground line 112.

In the latches 100, 200, the values of the electric potentials used for the retention, write and read operations can be different than the examples previously disclosed. Particularly, these values are adapted according to the whished features and performances of the latch.

With the latches 100, 200, several read and/or write operations can be successively carried out, without return in retention mode between each of these operations. However, because the memory comprising the latches 100, 200 is generally faster than the other electronic elements working with this memory, it is advantageous that the control circuit 101 puts the latches 100, 200 into the retention mode between each read and/or write operations.

1. Memory latch comprising at least:
a first tunnel field effect transistor TFET;
a capacitor;
a storage node formed by the connection of a first terminal of the capacitor to a first electrode of the first TFET corresponding to the source or the drain of the first TFET and configured to store a bit such that the low and high values of the electric potential of the storage node are representative of the value of the stored bit;
a control circuit configured to supply a first electric potential on a virtual ground line, a second electric potential on a word line connected to the gate of the first TFET and a third electric potential on a bit line;
wherein,
n a first configuration, a second terminal of the capacitor is connected to the virtual ground line, the first electrode of the first TFET corresponds to its source when the first TFET is n-type or to its drain when the first TFET is p-type, a second electrode of the first TFET corresponding to its drain when the first electrode corresponds to the source or to its source when the first electrode corresponds to the drain, is connected to the bit line, or
in a second configuration, a second terminal of the capacitor is connected to the bit line, the first electrode of the first TFET corresponds to its drain when the first TFET is n-type or to its source when the first TFET is p-type, a second electrode of the first TFET, corresponding to its source when the first electrode corresponds to the drain or to its drain when the first electrode corresponds to the source, is connected to the bit line;
and wherein the control circuit is configured to provide, during a retention of a bit stored in the storage node, the first, second and third electric potentials with values such that:
when the stored bit has a first value, a first bias voltage applied between the source and the drain of the first TFET has an absolute value less than that of a second bias voltage applied between the first and second terminals of the capacitor, and the first TFET is reverse biased such that a conduction current obtained by band-to-band tunneling in the first TFET has a value higher than a leakage current of the capacitor;
when the stored bit has a second value different than the first value, the first bias voltage has an absolute value greater than that of the second bias voltage and the first TFET is reverse biased such that an OFF state current obtained in the first TFET has a value less than the leakage current of the capacitor.

2. Memory latch according to claim 1, wherein the control circuit is configured to provide the first, second and third electric potentials with values such that:
in the first configuration, when the value of the electric potential of the storage node is low, the first TFET is reverse biased by the first bias voltage such that the conduction current obtained by band-to-band tunneling in the first TFET has a value higher than the leakage current of the capacitor;
in the first configuration, when the value of the electric potential of the storage node is high, the first TFET is reverse biased by the first bias voltage such that the OFF state current obtained in the first TFET has a value less than the leakage current of the capacitor;
in the second configuration, when the value of the electric potential of the storage node is low, the first TFET is reverse biased by the first bias voltage such that the OFF sate current obtained in the first TFET has a smaller value than the leakage current of the capacitor;
in the second configuration, when the value of the electric potential of the storage node is high, the first TFET is revered biased by the first bias voltage such that the conduction current obtained by band-to-band tunneling in the first TFET has a value greater than the leakage current of the capacitor.

3. Memory latch according to claim 1, wherein the control circuit is configured to provide, during the retention of a bit stored in the storage node, the first, second and third electric potentials such that the absolute value of the first electric potential is higher than the absolute value of the third electric potential, and that the absolute value of the second electric potential is higher than the absolute value of the first electric potential.

4. Memory latch according claim 1, wherein the control circuit is configured to provide, during the retention of a bit stored in the storage node, the first, second and third electric potentials such that the absolute value of the first electric potential is substantially equal to the high value of the electric potential of the storage node or that the absolute value of the third electric potential is substantially equal to the low value of an electric potential of the storage node, or that the absolute value of the first electric potential is substantially equal to the high value of the electric potential of the storage node and that the absolute value of the third electric potential is substantially equal to the low value of the electric potential of the storage node.

5. Memory latch according to claim 1, wherein the control circuit is configured to provide, during a writing of a bit in the storage node, the first, second and third electric potentials such that:
the first electric potential includes a write pulse triggering the writing of the bit in the storage node, and the value of the third electric potential is representative of the value of the bit to be written during at last part of the write pulse;
when the value of the bit to be written corresponds to the low value of the electric potential of the storage node, the first TFET is reverse biased in a state wherein a conduction current is obtained by thermionic emission over the barrier formed in the first TFET during the write pulse, discharging the storage node through the first TFET;
when the value of the bit to be written corresponds to the high value of the electric potential of the storage node, the first TFET is forward biased.

6. Memory latch according to claim 5, wherein:
during the writing of a bit corresponding to the low value of the electric potential of the storage node, the absolute value of the second electric potential is equal to or greater than the absolute value of the third electric potential, the absolute value of the first electric potential during the write pulse is equal or higher than the absolute value of the second electric potential, and
during the writing of a bit corresponding to the high value of the electric potential of the storage node, the absolute value of the third electric potential is equal or higher than the absolute value of the second electric potential, and the absolute value of the first electric potential during the write pulse is equal or higher than the absolute value of the second electric potential.

7. Memory latch according to claim 1, wherein the control circuit is configured to apply, during a reading of a bit stored in the storage node, a pre-charge electric potential on the bit line and then a pulse voltage on the gate of the first TFET such that the value of the electric potential on the bit line turns down during the pulse only if the value of the electric potential of the storage node is low.

8. Memory latch according to claim 1, further comprising:
a second TFET having its gate connected to the storage node and a first electrode, corresponding to its source when the second TFET is n-type or to its drain when the second TFET is p-type, connected to the word line,
a read bit line connected to a second electrode of the second TFET, corresponding to its drain when the first electrode corresponds to its source or to its source when the first electrode corresponds to its drain,
and wherein the control circuit is configured to apply, during a reading of a bit stored in the storage node, a read pulse on the word line such that the value of an electric potential on the read bit line turns down during the pulse only if the value of the electric potential of the storage node is high.

9. DRAM latches array, comprising several memory latches according to claim 1 and arranged according to an array of several rows and several columns, and wherein;
each word line is connected to the gate of the first TFET of each of the memory latches belonging to a same row of the array;
each virtual ground line is connected to each of the memory latches belonging to a same row of the array;
each bit line is connected to each of the memory latches belonging to a same column of the array;
the control circuit is common to all the memory latches of the DRAM latches array and configured to supply the electric potentials to said memory latches through the bit lines, the word lines and the virtual ground lines.

10. DRAM latches array according to claim 9, wherein the control circuit is configured to perform a writing operation collectively for one row of memory latches of the array such that:
the absolute value of an electric potential applied on the word line connected to the memory latches of said one row of memory latches is higher than the absolute value of an electric potential applied on the word lines connected to the other memory latches, then
the absolute values of the electric potentials applied on all the bit lines are set according to the values of the bits to be written in said one row of memory latches, and then
a write pulse is applied on the virtual ground line connected to the memory latches of said one row of memory latches.

11. DRAM latches array according to claim 9, wherein the control circuit is configured to perform a read operation collectively for one row of memory latches of the array such that:
the absolute value of the electric potentials applied on all the word lines are low, then
pre-charge electric potentials are applied on all the bit lines, and then
a read pulse is applied on the word line connected to the memory latches of said one row of memory latches.

12. SRAM latches array, comprising several memory latches according to claim 8 and arranged according to an array of several rows and several columns, and wherein;
each word line is connected to the gate of the first TFET and to the first electrode of the second TFET of each of the memory latches belonging to a same row of the array;
each virtual ground line is connected to each of the memory latches belonging to a same row of the array;
each read bit line and each bit line, called write bit line, are connected to each of the memory latches belonging to a same column of the array;
the control circuit is common to all the memory latches of the SRAM latches array and configured to supply the electric potentials to said memory latches through the read bit lines, the write bit lines, the word lines and the virtual ground lines.

13. SRAM latches array according to claim 12, wherein the control circuit is configured to perform a writing operation collectively for one row of memory latches of the array such that:
the absolute value of an electric potential applied on the word line connected to the memory latches of said one row of memory latches is higher than the absolute value of an electric potential applied on the word lines connected to the other memory latches, then
the absolute values of the electric potentials applied on all the write bit lines are set according to the values of the bits to be written in said one row of memory latches, and then
a write pulse is applied on the virtual ground line connected to the memory latches of said one row of memory latches.

14. SRAM latches array according to claim 12, wherein the control circuit is configured to perform a read operation collectively for one row of memory latches of the array such that:
the absolute value of the electric potentials applied on all the word lines are high, then
a read pulse is applied on the word line connected to the memory latches of said one row of memory latches.

15. Flip-flop comprising at least:
first and second memory latches according claim 1;
a first inverter having an input forming the input of the flip-flop and an output connected to the storage node of the first latch;
a second inverter having an input connected to the storage node of the first latch and an output connected to the storage node of the second latch.
